(19) United States
(12) Patent Application Publication
(10) Pub. No.: US 2023/0262931 A1
(43) Pub. Date: Aug. 17, 2023

(54) TWO-PHASE IMMERSION-TYPE HEAT DISSIPATION SUBSTRATE STRUCTURE

(71) Applicant: AMULAIRE THERMAL TECHNOLOGY, INC., New Taipei City (TW)

(72) Inventors: CHENG-SHU PENG, New Taipei City (TW); MING-CHIH CHEN, Keelung City (TW)

(21) Appl. No.: 17/669,480

(22) Filed: Feb. 11, 2022

(51) Int. Cl. H05K 7/20

(52) U.S. Cl. CPC H05K 7/203; H05K 7/20409; H05K 7/20272

(57) ABSTRACT

A two-phase immersion-type heat dissipation substrate structure which is used for contacting a heat generating element provided. The two-phase immersion-type heat dissipation substrate structure includes an immersion-type heat dissipation substrate and a fin assembly. The immersion-type heat dissipation substrate has a front side and a back side that is opposite to the front side, the back side is used for contacting the heat generating element, and the front side has the fin assembly arranged thereon. The fin assembly includes a plurality of fins that are perpendicular to the front side, and the front side and the back side are not parallel to each other, so that an extension direction of each of the plurality of fins is neither perpendicular to nor parallel to a direction along which vapor bubbles escape.

### FIELD OF THE DISCLOSURE

The present disclosure relates to a heat dissipation substrate structure, and more particularly to a two-phase immersion-type heat dissipation substrate structure.

### BACKGROUND OF THE DISCLOSURE

An immersion cooling technology is to directly immerse heat generating elements (such as servers and disk arrays) into a coolant that is non-conductive, and heat generated from operation of the heat generating elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides a two-phase immersion-type heat dissipation substrate structure.

In one aspect, the present disclosure provides a two-phase immersion-type heat dissipation substrate structure which is used for contacting a heat generating element. The two-phase immersion-type heat dissipation substrate structure includes an immersion-type heat dissipation substrate and a fin assembly. The immersion-type heat dissipation substrate has a front side and a back side that is opposite to the front side, the back side of the immersion-type heat dissipation substrate is used for contacting the heat generating element, and the front side of the immersion-type heat dissipation substrate has the fin assembly arranged thereon. The fin assembly includes a plurality of fins that are perpendicular to the front side of the immersion-type heat dissipation substrate, and the front side of the immersion-type heat dissipation substrate and the back side of the immersion-type heat dissipation substrate are not parallel to each other, so that an extension direction of each of the plurality of fins is neither perpendicular to nor parallel to a direction along which vapor bubbles escape.

In certain embodiments, the immersion-type heat dissipation substrate is made of aluminum, copper, aluminum alloy, or copper alloy.

In certain embodiments, each of the plurality of fins is integrally formed and arranged vertically on the front side of the immersion-type heat dissipation substrate by metal injection molding.

In certain embodiments, each of the plurality of fins is a porous metal heat dissipation fin that has a porosity greater than 7% and that is capable of being immersed in a two-phase coolant.

In certain embodiments, an angle between 10 degrees and 20 degrees is formed between the front side of the immersion-type heat dissipation substrate and the back side of the immersion-type heat dissipation substrate.

In another aspect, the present disclosure provides a two-phase immersion-type heat dissipation substrate structure which is used for contacting a heat generating element. The two-phase immersion-type heat dissipation substrate structure includes an immersion-type heat dissipation substrate, a first fin assembly, and a second fin assembly. The immersion-type heat dissipation substrate has a front side and a back side that is opposite to the front side, the back side of the immersion-type heat dissipation substrate is used for contacting the heat generating element, the front side of the immersion-type heat dissipation substrate has the first fin assembly and the second fin assembly arranged thereon, and the first fin assembly and the second fin assembly are sequentially arranged on the front side of the immersion-type heat dissipation substrate in a direction along which vapor bubbles escape. The first fin assembly includes a plurality of first fins vertically arranged on the front side of the immersion-type heat dissipation substrate, and the second fin assembly includes a plurality of second fins vertically arranged on the front side of the immersion-type heat dissipation substrate. A height of each of a plurality of first fins is greater than a height of each of a plurality of second fins, and the front side of the immersion-type heat dissipation substrate and the back side of the immersion-type heat dissipation substrate are not parallel to each other, so that a direction of each of the plurality of first fins and a direction of each of the plurality of second fins are neither perpendicular to nor parallel to the direction along which the vapor bubbles escape.

In certain embodiments, a thickness of a cross-section of the immersion-type heat dissipation substrate is gradually decreased along the direction along which the vapor bubbles escape, a position of the first fin assembly corresponds to one area of the immersion-type heat dissipation substrate that has a thicker cross-section, and a position of the second fin assembly corresponds to another area of the immersion-type heat dissipation substrate that has a thinner cross-section, a position of the one area of the immersion-type heat dissipation substrate that has the thicker cross-section corresponds to a high temperature region of the heat generating element, and a position of the another area of the immersion-type heat dissipation substrate that has the thinner cross-section corresponds to a non-high temperature region of the heat generating element.

In certain embodiments, each of the plurality of first fins and each of the plurality of second fins are integrally formed and arranged vertically on the front side of the immersion-type heat dissipation substrate by metal injection molding.

In certain embodiments, each of the plurality of first fins and each of the plurality of second fins are porous metal heat dissipation fins that each has a porosity greater than 7% and that is capable of being immersed in a two-phase coolant.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a two-phase immersion-type heat dissipation substrate structure according to a first embodiment of the present disclosure; and

FIG. 2 is a schematic side view of a two-phase immersion-type heat dissipation substrate structure according to a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

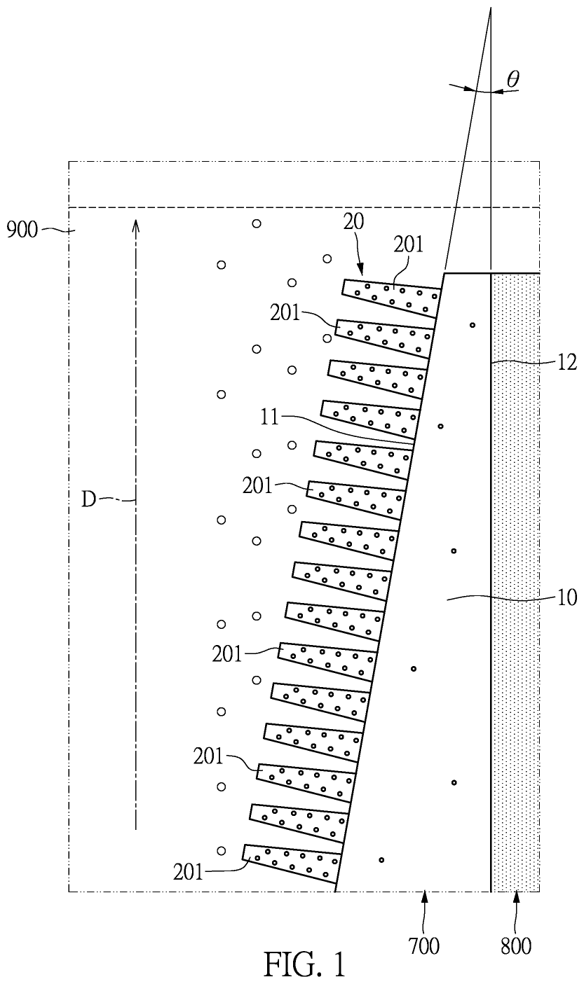

Reference is made to FIG. 1, in which one embodiment of the present disclosure is shown. Embodiments of the present disclosure provide a two-phase immersion-type heat dissipation substrate structure 700 that can be used for contacting a heat generating element 800. As shown in FIG. 1, the two-phase immersion-type heat dissipation substrate structure 700 provided by the embodiments of the present disclosure essentially includes an immersion-type heat dissipation substrate 10 and a fin assembly 20.

In the present embodiment, the immersion-type heat dissipation substrate 10 can be made of a high thermally conductive material, such as aluminum, copper, aluminum alloy, and copper alloy. Further, the immersion-type heat dissipation substrate 10 of the present embodiment can be a porous metal heat sink that can be immersed in a two-phase coolant 900 (such as electronic fluorinated liquid) and that has a porosity greater than 5%. Accordingly, generation of vapor bubbles can be increased and an immersion-type heat dissipation effect can be enhanced. It should be noted that, porous structure are exaggeratedly enlarged in FIG. 1 for a better understanding of the present disclosure.

In the present embodiment, the immersion-type heat dissipation substrate 10 has a front side 11 and a back side 12 that is opposite to the front side 11. The back side 12 of the immersion-type heat dissipation substrate 10 is used for contacting the heat generating element 800. The front side 11 of the immersion-type heat dissipation substrate 10 has the fin assembly 20 arranged thereon.

Further, the fin assembly 20 of the present embodiment includes a plurality of fins 201 that are perpendicular to the front side 11 of the immersion-type heat dissipation substrate 10. Each of the plurality of fins 201 can be a plate fin or a pin fin. In addition, each of the plurality of fins 201 can be integrally formed and arranged vertically on the front side 11 of the immersion-type heat dissipation substrate 10 by metal injection molding, and the plurality of fins 201 are immersed in the two-phase coolant 900. In addition, each of the plurality of fins 201 of the present embodiment is a porous metal heat dissipation fin, that is, the fin assembly 20 of the present embodiment is formed by multiple ones of the porous metal heat dissipation fins. Further, a porosity of the fin 201 of the present embodiment is greater than a porosity of the immersion-type heat dissipation substrate 10. Further, the fin 201 of the present embodiment is a porous metal heat dissipation fin that has a porosity greater than 7% and that is immersed in the two-phase coolant 900, such that the generation of vapor bubbles can be further increased. In addition, the front side 11 and the back side 12 of the immersion-type heat dissipation substrate 10 of the present embodiment are not parallel to each other, so that an extension direction of each of the plurality of fins 201 is neither perpendicular to nor parallel to a direction along which the vapor bubbles escape D. Therefore, a resistance against vapor bubbles escaping upward when a large number of vapor bubbles are generated can be reduced, and an efficiency of a replenishment of surrounding fluid can be increased, thereby further increasing an overall immersion-type heat dissipation effect. In addition, after actual testing, an optimal overall immersion-type heat dissipation effect can be achieved when an angle θ between 10 degrees and 20 degrees is formed between the front side 11 and the back side 12 of the immersion-type heat dissipation substrate 10.

### Second Embodiment

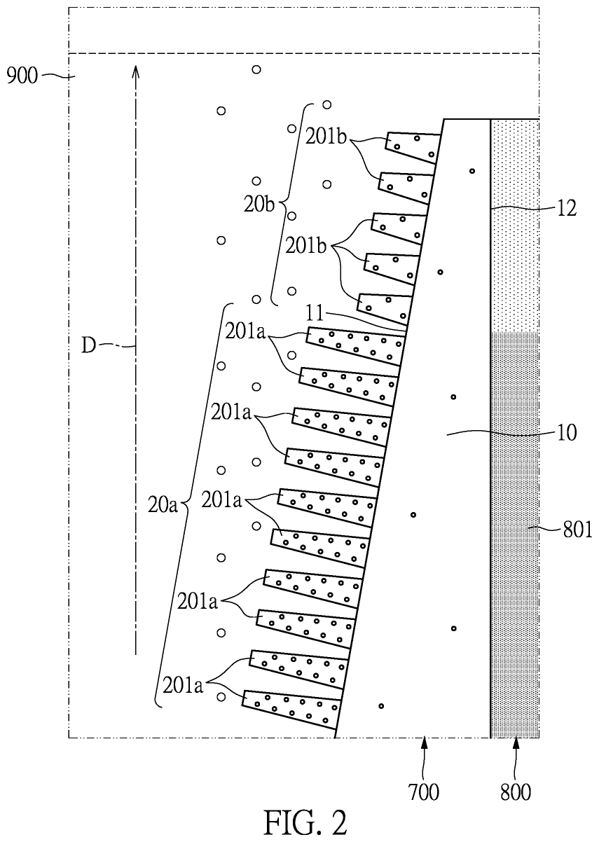

Reference is made to FIG. 2, in which a second embodiment of the present disclosure is shown. The present embodiment is substantially the same as the first embodiment, and differences therebetween are described as follows.

In the present embodiment, the immersion-type heat dissipation substrate 10 has the front side 11 and the back side 12 that is opposite to the front side 11. The back side 12 of the immersion-type heat dissipation substrate 10 is used for contacting the heat generating element 800. The front side 11 of the immersion-type heat dissipation substrate 10 has a first fin assembly 20a and a second fin assembly 20b arranged thereon.

Further, the first fin assembly 20a and the second fin assembly 20b of the present embodiment are sequentially arranged on the front side 11 of the immersion-type heat dissipation substrate 10 along the direction along which the vapor bubbles escape D, that is, the first fin assembly 20a and the second fin assembly 20b are sequentially arranged on the front side 11 of the immersion-type heat dissipation substrate 10 along a direction opposite to a direction of gravity. In addition, a height of each of a plurality of first fins 201a of the first fin assembly 20 is greater than a height of each of a plurality of second fins 201b of the second fin assembly 20b, and the front side 11 and the back side 12 of the immersion-type heat dissipation substrate 10 are not parallel to each other. Therefore, when a large number of vapor bubbles generated in the first fin assembly 20a and a peripheral area thereof escape along the direction along which the vapor bubbles escape D (i.e., upward), resistance against escaping vapor bubbles resulting from interference of the second fin assembly 20b can be significantly reduced.

Further, as shown in FIG. 2, a thickness of a cross-section of the immersion-type heat dissipation substrate 10 is gradually decreased along the direction along which the vapor bubbles escape D (i.e., upward), so that a position of the first fin assembly 20a corresponds to one area of the immersion-type heat dissipation substrate 10 that has a greater thickness, and a position of the second fin assembly 20b corresponds to another area of the immersion-type heat dissipation substrate 10 that has a smaller thickness. In addition, a position of the one area of the immersion-type heat dissipation substrate 10 that has the greater thickness corresponds to a predetermined high temperature region 801 of the heat generating element 800, and a position of the another area of the immersion-type heat dissipation substrate 10 that has the smaller thickness corresponds to a non-high temperature region of the heat generating element 800, which can also be referred to as a low temperature region of the heat generating element 800 where heating temperature is relatively low. Therefore, the position of the first fin assembly 20a that has fins that are higher corresponds to the predetermined high temperature region 801 of the heat generating element 800, and the position of the second fin assembly 20b that has fins that are lower corresponds to the non-high temperature region of the heat generating element 800, so that high heat generated in the high temperature region 801 of the heat generating element 800 can be effectively carried away therefrom, so as to further increase the immersion-type heat dissipation effect.

### Beneficial Effects of the Embodiments

In conclusion, one of the beneficial effects of the present disclosure is that, in the two-phase immersion-type heat dissipation substrate structure provided by the present disclosure, by virtue of “the immersion-type heat dissipation substrate having the front side and the back side that is opposite to the front side”, “the back side of the immersion-type heat dissipation substrate being used for contacting the heat generating element, and the front side of the immersion-type heat dissipation substrate having the fin assembly arranged thereon”, “the fin assembly including the plurality of fins that are perpendicular to the front side of the immersion-type heat dissipation substrate, and the front side of the immersion-type heat dissipation substrate and the back side of the immersion-type heat dissipation substrate being not parallel to each other, so that the extension direction of each of the plurality of fins is neither perpendicular to nor parallel to the direction along which the vapor bubbles escape,” the resistance against vapor bubbles escaping upward when the large number of vapor bubbles are generated can be reduced, and the efficiency of the replenishment of the surrounding fluid can be increased, thereby increasing the overall immersion-type heat dissipation effect.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-phase immersion-type heat dissipation substrate structure which is used for contacting a heat generating element, comprising:
an immersion-type heat dissipation substrate; and
a fin assembly;
wherein the immersion-type heat dissipation substrate has a front side and a back side that is opposite to the front side, the back side of the immersion-type heat dissipation substrate is used for contacting the heat generating element, and the front side of the immersion-type heat dissipation substrate has the fin assembly arranged thereon;
wherein the fin assembly includes a plurality of fins that are perpendicular to the front side of the immersion-type heat dissipation substrate, and the front side of the immersion-type heat dissipation substrate and the back side of the immersion-type heat dissipation substrate are not parallel to each other, so that an extension direction of each of the plurality of fins is neither perpendicular to nor parallel to a direction along which vapor bubbles escape.

2. The two-phase immersion-type heat dissipation substrate structure according to claim 1, wherein the immersion-type heat dissipation substrate is made of aluminum, copper, aluminum alloy, or copper alloy.

3. The two-phase immersion-type heat dissipation substrate structure according to claim 1, wherein each of the plurality of fins is integrally formed and arranged vertically on the front side of the immersion-type heat dissipation substrate by metal injection molding.

4. The two-phase immersion-type heat dissipation substrate structure according to claim 3, wherein each of the plurality of fins is a porous metal heat dissipation fin that has a porosity greater than 7% and that is capable of being immersed in a two-phase coolant.

5. The two-phase immersion-type heat dissipation substrate structure according to claim 1, wherein an angle between 10 degrees and 20 degrees is formed between the front side of the immersion-type heat dissipation substrate and the back side of the immersion-type heat dissipation substrate.

6. A two-phase immersion-type heat dissipation substrate structure which is used for contacting a heat generating element, comprising:
an immersion-type heat dissipation substrate;
a first fin assembly; and
a second fin assembly;
wherein the immersion-type heat dissipation substrate has a front side and a back side that is opposite to the front side, the back side of the immersion-type heat dissipation substrate is used for contacting the heat generating element, the front side of the immersion-type heat dissipation substrate has the first fin assembly and the second fin assembly arranged thereon, and the first fin assembly and the second fin assembly are sequentially arranged on the front side of the immersion-type heat dissipation substrate in a direction along which vapor bubbles escape;
wherein the first fin assembly includes a plurality of first fins vertically arranged on the front side of the immersion-type heat dissipation substrate, and the second fin assembly includes a plurality of second fins vertically arranged on the front side of the immersion-type heat dissipation substrate;
wherein a height of each of a plurality of first fins is greater than a height of each of a plurality of second fins, and the front side of the immersion-type heat dissipation substrate and the back side of the immersion-type heat dissipation substrate are not parallel to each other, so that a direction of each of the plurality of first fins and a direction of each of the plurality of second fins are neither perpendicular to nor parallel to the direction along which the vapor bubbles escape.

7. The two-phase immersion-type heat dissipation substrate structure according to claim 6, wherein a thickness of a cross-section of the immersion-type heat dissipation substrate is gradually decreased along the direction along which the vapor bubbles escape, a position of the first fin assembly corresponds to one area of the immersion-type heat dissipation substrate that has a thicker cross-section, and a position of the second fin assembly corresponds to another area of the immersion-type heat dissipation substrate that has a thinner cross-section, a position of the one area of the immersion-type heat dissipation substrate that has the thicker cross-section corresponds to a high temperature region of the heat generating element, and a position of the another area of the immersion-type heat dissipation substrate that has the thinner cross-section corresponds to a non-high temperature region of the heat generating element.

8. The two-phase immersion-type heat dissipation substrate structure according to claim 6, wherein the immersion-type heat dissipation substrate is made of aluminum, copper, aluminum alloy, or copper alloy.

9. The two-phase immersion-type heat dissipation substrate structure according to claim 6, wherein each of the plurality of first fins and each of the plurality of second fins are integrally formed and arranged vertically on the front side of the immersion-type heat dissipation substrate by metal injection molding.

10. The two-phase immersion-type heat dissipation substrate structure according to claim 9, wherein each of the plurality of first fins and each of the plurality of second fins are porous metal heat dissipation fins that each has a porosity greater than 7% and that is capable of being immersed in a two-phase coolant.
